(19) United States
(12) Patent Application Publication
(10) Pub. No.: US 2026/0227707 A1
(43) Pub. Date: Aug. 6, 2026

(54) ESTIMATION METHOD, CONTROL METHOD AND CONTROL DEVICE

(71) Applicant: SCREEN Holdings Co., Ltd., Kyoto (JP)

(72) Inventor: Kenji NAKANISHI, Kyoto-shi, Kyoto (JP)

(21) Appl. No.: 19/146,327

(22) PCT Filed: Dec. 19, 2023
(86) PCT No.: PCT/JP2023/045527

§ 371 Date: Jul. 8, 2025

(30) Foreign Application Priority Data
Feb. 24, 2023 (JP) 2023-026879

(51) Int. Cl. G03F 7/00; G03F 7/20

(52) U.S. Cl. CPC G03F 7/70516; G03F 7/2006; G03F 7/70025

(57) ABSTRACT

An imaging system to irradiate a base material with laser is subjected to a step of acquiring temperature distribution data representing a temperature distribution at the imaging system, an estimation step of inputting the temperature distribution data to a learned model and acquiring an estimated exposure result that is an estimation of an exposure result output from the learned model, and a distortion amount calculation step of calculating a distortion amount of a laser irradiation position from the estimated exposure result. This allows a distortion amount of a laser irradiation position to be estimated in a short time. Thus, it is possible to align laser in a short time. As a result, deviation of a laser irradiation position can be reduced in a shorter time than calibration and an interval during the calibration can be expanded.

### TECHNICAL FIELD

The present invention relates to an estimation method of estimating a distortion amount of a laser irradiation position in a laser imaging system, and a control method and a control device for the laser imaging system.

### BACKGROUND ART

An imaging system conventionally known performs pattern exposure through laser irradiation on a base material that may be glass, a printed board, or a wafer coated with a resist. The imaging system of this type is required to perform exposure in correct alignment with a layer formed previously or with a hole in the base material, for example. However, alignment accuracy may be reduced by laser drift caused by change in a temperature distribution at each part of the device.

To compensate for such deviation of the laser irradiation position, calibration is generally performed at regular intervals. According to the calibration, a laser irradiation position is detected, for example, using a camera, deviation of the laser irradiation position is detected, and the laser irradiation position is compensated for on the basis of the amount of the deviation. A method of compensating for the deviation of the laser irradiation position is shown in Patent Literature 1, for example.

### CITATION LIST

### Patent Literature

Patent Literature 1: Japanese Patent Application Laid-Open No. 2020-52647

### SUMMARY OF INVENTION

### Technical Problem

Preferably, the calibration is performed frequently in order to keep the laser alignment accuracy at a high level. However, taking time for the calibration causes a problem of worsening takt in manufacturing the base material. This arises a need for a technique for reducing deviation of the laser irradiation position and expanding an interval during the calibration.

The present invention has been made in view of these circumstances, and is intended to provide a technique for reducing deviation of a laser irradiation position in a shorter time than calibration and expanding an interval during the calibration.

### Solution to Problem

To solve the above problem, a first invention of the present application is intended for an estimation method of estimating a distortion amount of a laser irradiation position in an imaging system to irradiate a base material with laser, comprising: a) a step of acquiring temperature distribution data representing a temperature distribution at the imaging system; b) an estimation step of inputting the temperature distribution data to a learned model and acquiring an estimated exposure result that is an estimation of an exposure result output from the learned model; and c) a distortion amount calculation step of calculating a distortion amount of a laser irradiation position from the estimated exposure result.

According to a second invention of the present application, the estimation method according to the first invention further comprises: d) a learning step performed before the steps a), b), and c). The learning step generates the learned model through machine learning capable of estimating the exposure result prediction using the temperature distribution data as an input variable and using exposure result data as teaching data that corresponds to the temperature distribution data.

According to a third invention of the present application, in the estimation method according to the first invention, a thermal distribution image is photographed as the temperature distribution data using a thermography camera in the step a).

According to a fourth invention of the present application, in the estimation method according to the first invention, using a plurality of temperature sensors provided in a plurality of positions at the imaging system, measured values are acquired from the plurality of temperature sensors as the temperature distribution data in the step a).

A fifth invention of the present application is intended for a control method for an imaging system to irradiate a base material with laser, comprising: P) a step of estimating a distortion amount of a laser irradiation position through the estimation method according to any one of the first to fourth inventions; Q) a step of acquiring an exposure pattern; R) a step of generating a compensated exposure pattern by compensating for a laser irradiation position in the exposure pattern on the basis of the estimated distortion amount; and S) a step of irradiating the base material with laser on the basis of the compensated exposure pattern.

A sixth invention of the present application is intended for a control device for an imaging system to irradiate a base material with laser, comprising: an estimation part that inputs temperature distribution data representing a temperature distribution at the imaging system to a learned model and acquires an estimated exposure result that is an estimation of an exposure result output from the learned model; a distortion amount calculation part that calculates a distortion amount of a laser irradiation position from the estimated exposure result; an exposure pattern compensation part that generates a compensated exposure pattern by compensating for a laser irradiation position in an exposure pattern on the basis of the calculated distortion amount; and an imaging implementation part that irradiates the base material with laser on the basis of the compensated exposure pattern.

A seventh invention of the present application is intended for an estimation method of estimating a distortion amount of a laser irradiation position in an imaging system to irradiate a base material with laser, comprising: a) a step of acquiring temperature distribution data representing a temperature distribution at the imaging system; and b) an estimation step of inputting the temperature distribution data to a learned model and acquiring a distortion amount of a laser irradiation position output from the learned model.

An eighth invention of the present application is intended for a control device for an imaging system to irradiate a base material with laser, comprising: an estimation part that inputs temperature distribution data representing a temperature distribution at the imaging system to a learned model and acquires a distortion amount of a laser irradiation position output from the learned model; an exposure pattern compensation part that generates a compensated exposure pattern by compensating for a laser irradiation position in an exposure pattern on the basis of the distortion amount; and an imaging implementation part that irradiates the base material with laser on the basis of the compensated exposure pattern.

### ADVANTAGEOUS EFFECTS OF INVENTION

According to the first to eighth inventions of the present application, it is possible to estimate a distortion amount of a laser irradiation position in a short time using the learned model. By aligning laser using the estimated distortion amount, it becomes possible to expand an interval during calibration.

In particular, according to the fifth and sixth inventions of the present application, it is possible to improve accuracy of laser alignment in a short time.

### BRIEF DESCRIPTION OF DRAWINGS

FIG. 1 is a perspective view of an imaging system.

FIG. 2 is a block diagram showing electrical connection between a controller and each part in the imaging system.

FIG. 3 is a control block diagram showing a distortion amount estimation unit and an imaging control unit.

FIG. 4 is a flowchart showing a flow of a learning process.

FIG. 5 is a flowchart showing a flow of an imaging process.

FIG. 6 is a control block diagram showing a distortion amount estimation unit and an imaging control unit according to one modification.

FIG. 7 includes views showing an example of a learning exposure pattern and examples of a learning exposure result according to one modification.

FIG. 8 is a flowchart showing a flow of an imaging process according to a different modification.

FIG. 9 is a control block diagram showing a distortion amount estimation unit and an imaging control unit according to a different modification.

### DESCRIPTION OF EMBODIMENTS

An embodiment of the present invention will be described below by referring to the drawings.

### 1. Configuration of Imaging System

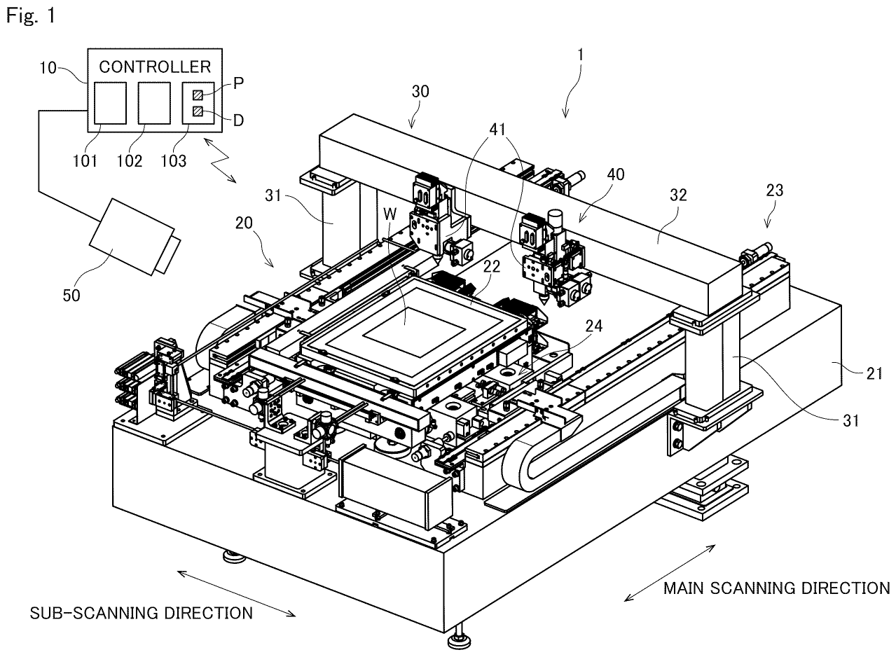

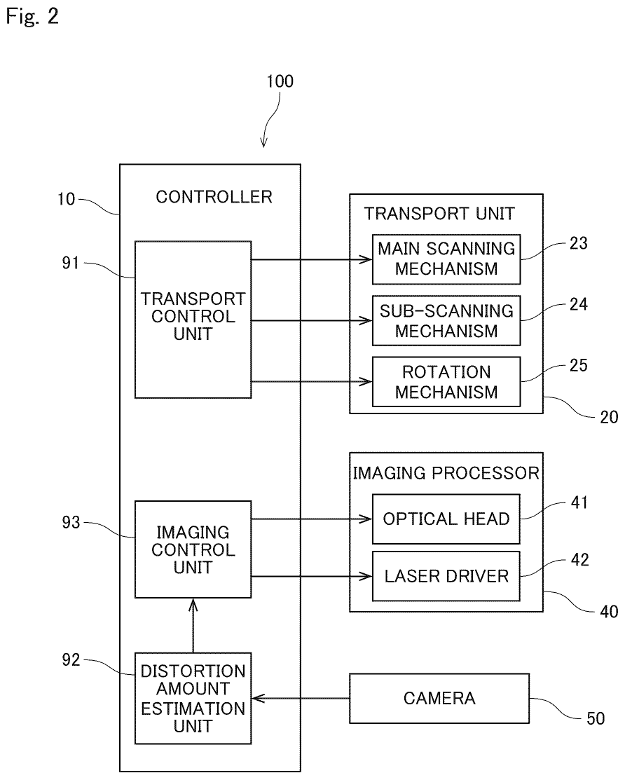

The following describes an imaging system 1 according to one embodiment of the present invention by referring to FIGS. 1 and 2. FIG. 1 is a perspective view of the imaging system 1. FIG. 2 is a block diagram showing electrical connection between a controller 10 and each part in the imaging system.

The imaging system 1 is a device to form an exposure pattern on an upper surface of a base material by applying spatially-modulated light. The base material targeted for imaging by the imaging system 1 of the present embodiment is a substrate W that may be a semiconductor substrate or a glass substrate coated with a photosensitive material. As shown in FIGS. 1 and 2, the imaging system 1 includes a transport unit 20, a frame 30, an imaging processor 40, a camera 50, and the controller 10. The transport unit 20, the frame 30, the imaging processor 40, and the camera 50 of the imaging system 1 except the controller 10 are housed in a chamber (not shown in the drawings).

The transport unit 20 is a unit to transport a stage 22 like a flat plate on an upper surface of a base 21 in a horizontal direction while keeping the stage 22 in a substantially constant posture. The transport unit 20 includes a main scanning mechanism 23, a sub-scanning mechanism 24, and a rotation mechanism 25 (see FIG. 2). The main scanning mechanism 23 is a mechanism for transporting the stage 22 in a main scanning direction as one direction of the horizontal direction. The sub-scanning mechanism 24 is a mechanism for transporting the stage 22 in a sub-scanning direction as one direction of the horizontal direction and orthogonal to the main scanning direction. The substrate W is held in a horizontal posture on an upper surface of the stage 22 and moved in the main scanning direction and the sub-scanning direction together with the stage 22. The rotation mechanism 25 is capable of adjusting the position of the stage 22 about a vertical axis relative to the base 21.

The frame 30 is a structure for holding the imaging processor 40 over the base 21. The frame 30 includes column parts 31 in a pair and a bridge part 32. The column parts 31 in a pair are provided upright while spaced from each other in the sub-scanning direction. Each of the column parts 31 extends upward from the upper surface of the base 21. The bridge part 32 extends in the sub-scanning direction between respective upper ends of the two column parts 31. The stage 22 holding the substrate W thereon passes between the column parts 31 in a pair and under the bridge part 32.

The imaging processor 40 includes two optical heads 41. The two optical heads 41 are fixed to the bridge part 32 while spaced from each other in the sub-scanning direction. The imaging processor 40 includes an illumination optical system and a laser oscillator not shown in the drawings, and a laser driver 42 (see FIG. 2). The illumination optical system, the laser oscillator, and the laser driver 42 are housed in an internal space of the bridge part 32, for example. The laser driver 42 is electrically connected to the laser oscillator. By causing the laser driver 42 to operate, pulsed light is emitted from the laser oscillator. The pulsed light emitted from the laser oscillator is introduced into the optical head 41 via the illumination optical system.

An optical system including a spatial modulator is provided inside the optical head 41. The pulsed light introduced in the optical head 41 is modulated into a predetermined pattern by the spatial modulator and then applied to an upper surface of the substrate W. By doing so, the photosensitive material such as a resist applied to the upper surface of the substrate W is exposed to light.

The camera 50 is a thermography camera capable of acquiring a temperature distribution at the imaging system 1 as an image. The camera 50 photographs a thermal distribution image as temperature distribution data Hm. While one camera 50 is provided in response to one imaging system 1 in the present embodiment, two or more cameras 50 may be provided in response to one imaging system 1.

A range of photographing by the camera 50 is specifically a measurement range of a temperature distribution. A range of photographing by the camera 50 is preferably covers the imaging system 1 entirely. Preferably, a range of photographing by the camera 50 includes at least the substrate W, the stage 22 on which the substrate W is placed, and the laser oscillator and the laser driver 42 that are places to generate heat.

The controller 10 controls the operation of each part of the imaging system 1. The controller 10 functions as a control device for the imaging system 1. As conceptually shown in FIG. 1, the controller 10 is configured using a computer including a processor 101 such as a CPU, a memory 102 such as a RAM, and a storage 103 such as a hard disk drive. The storage 103 stores a computer program P for controlling the operation of the imaging system 1.

As shown in FIG. 2, the controller 10 is electrically connected to the main scanning mechanism 23, the sub-scanning mechanism 24, and the rotation mechanism 25 of the transport unit 20, to the optical head 41 and the laser driver 42 of the imaging processor 40, and to the camera 50. The controller 10 reads the computer program P and data D stored in the storage 103 into the memory 102, and the processor 101 performs arithmetic processing on the basis of the read computer program P and data D, thereby controlling the operation of each part in the imaging system 1 described above. As a result, an imaging process proceeds in the imaging system 1.

The controller 10 includes a transport control unit 91, a distortion amount estimation unit 92, and an imaging control unit 93. The respective functions of the distortion amount estimation unit 92, the transport control unit 91, and the imaging control unit 93 are realized by causing the processor 101 of the computer forming the controller 10 to operate according to the computer program P.

The transport control unit 91 controls each part of the transport unit 20. The transport control unit 91 transports the substrate W in a predetermined way during the imaging process.

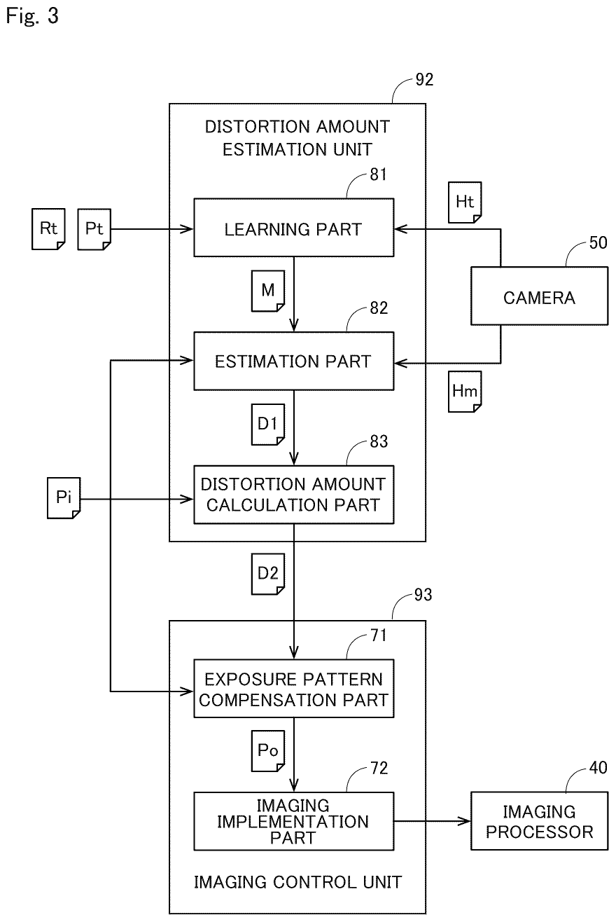

FIG. 3 is a control block diagram showing the distortion amount estimation unit 92 and the imaging control unit 93. As shown in FIG. 3, the distortion amount estimation unit 92 estimates a distortion amount of a laser irradiation position on the basis of the temperature distribution data Hm entered from the camera 50. More specifically, the distortion amount estimation unit 92 includes a learning part 81, an estimation part 82, and a distortion amount calculation part 83.

The learning part 81 learns a machine learning model to be used in estimation of a distortion amount by the estimation part 82, thereby generating a learned model M. For implementation of a step of learning the machine learning model by the learning part 81, learning temperature distribution data Ht acquired by the camera 50, a learning exposure pattern Pt, and a learning exposure result Rt corresponding to the learning temperature distribution data Ht are prepared in advance. The learning exposure result Rt corresponding to the learning temperature distribution data Ht is a learning exposure result Rt obtained by photographing the substrate W on which the learning exposure pattern Pt is formed by the imaging system 1 immediately after acquisition of the learning temperature distribution data Ht. Regarding photographing of the learning exposure result Rt, photographic equipment outside the imaging system 1 is used.

The learning part 81 generates the learned model M through machine learning using the learning temperature distribution data Ht and the learning exposure pattern Pt as input variables and using the learning exposure result Rt as teaching data that corresponds to the learning temperature distribution data Ht. In response to input of the temperature distribution data Hm entered from the camera 50 and an exposure pattern Pi to the learned model M, the learned model M becomes capable of estimating an exposure result about the exposure pattern Pi in line with a corresponding temperature distribution to output an estimated exposure result D1.

The estimation part 82 contains the learned model M generated by the learning part 81. The estimation part 82 inputs the temperature distribution data Hm entered from the camera 50 to the learned model M, and transfers the estimated exposure result D1 output from the learned model M to the distortion amount calculation part 83.

The distortion amount calculation part 83 calculates a distortion amount D2 of a laser irradiation position on the basis of the exposure pattern Pi and the estimated exposure result D1. The distortion amount D2 is obtained through calculation, and shows a direction and a degree of distortion occurring in each area of the estimated exposure result D1 in comparison to the exposure pattern Pi. As an example, the distortion amount D2 is calculated as a vector map showing a difference in terms of a vector quantity obtained between a coordinate in the estimated exposure result D1 and a coordinate in the exposure pattern Pi about each position corresponding to a predetermined reference coordinate in the exposure pattern Pi. The distortion amount calculation part 83 transfers the calculated distortion amount D2 to the imaging control unit 93.

The imaging control unit 93 includes an exposure pattern compensation part 71 and an imaging implementation part 72.

The exposure pattern compensation part 71 compensates for the exposure pattern Pi on the basis of the distortion amount D2 transferred from the distortion amount calculation part 83 of the distortion amount estimation unit 92, thereby generating a compensated exposure pattern Po. The exposure pattern compensation part 71 generates the compensated exposure pattern Po, for example, by deforming the exposure pattern Pi in a direction of cancelling the distortion amount D2 in each coordinate. Then, the exposure pattern compensation part 71 transfers the compensated exposure pattern Po to the imaging implementation part 72.

The imaging implementation part 72 controls the operation of the imaging processor 40 according to the compensated exposure pattern Po to irradiate the substrate W with laser, thereby forming a pattern comparable to the exposure pattern Pi on the upper surface of the substrate W. At this time, while the imaging processor 40 tries to form a pattern conforming to the compensated exposure pattern Po on the upper surface of the substrate W, a drift approximate to the calculated distortion amount D2 occurs in laser light from the imaging processor 40 toward the substrate W. Thus, the pattern to be eventually formed on the upper surface of the substrate W becomes approximate to the exposure pattern Pi.

When the imaging system 1 is working, the transport unit 20 is caused to operate by the transport control unit 91 and the imaging processor 40 is caused to operate by the imaging implementation part 72 in conjunction with each other. More specifically, exposure by the optical head 41 and the transport of the substrate W by the transport unit 20 are performed repeatedly. Still more specifically, pulsed light is applied from the optical head 41 while the stage 22 is transported in the main scanning direction by the main scanning mechanism 23, thereby exposing a strip-shaped region (swath) extending in the main scanning direction to light. The stage 22 is thereafter transported by one swath in the sub-scanning direction by the sub-scanning mechanism 24. The imaging system 1 repeats such exposure in the main scanning direction and transport of the stage 22 in the sub-scanning direction, thereby forming a pattern on the entire upper surface of the substrate W.

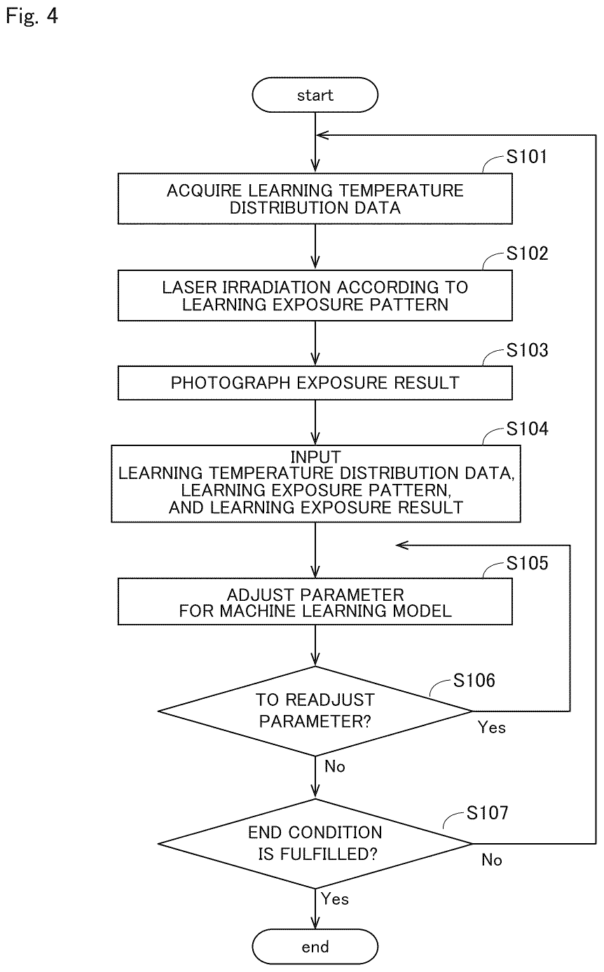

2. Process of Learning Machine Learning Model Described next is a process of learning a machine learning model performed by the learning part 81 described above. FIG. 4 is a flowchart showing a flow of the learning process. This learning process is performed before the substrate W to become a product is subjected to a pattern exposure process.

As shown in FIG. 4, in performing the learning process, the controller 10 first causes the camera 50 to acquire the learning temperature distribution data Ht representing a temperature distribution at the imaging system 1 on which the substrate W is installed (step S101). With minimum possible delay thereafter, specifically, within a period when the temperature distribution at the imaging system 1 does not change from acquisition of the learning temperature distribution data Ht, the controller 10 forms the learning exposure pattern Pt on the upper surface of the substrate W (step S102). Then, the upper surface of the substrate W on which the pattern is formed in step S102 is photographed to acquire the learning exposure result Rt (step S103).

At the beginning of the learning process, namely, before a subsequent step of learning the machine learning model (steps S104 and S105) is performed for the first time, steps S101 to S103 may be performed several times to acquire a plurality of learning datasets each containing the learning temperature distribution data Ht, the learning exposure pattern Pt, and the learning exposure result Rt. In this case, a plurality of learning datasets containing the same learning exposure pattern Pt may be acquired. Meanwhile, in the presence of the learning exposure patterns Pt of several types, a plurality of learning datasets containing respective ones of these learning exposure patterns Pt may be acquired.

Next, the learning part 81 performs machine learning of the machine learning model (steps S104 and S105) using the learning dataset acquired in steps S101 to S103. More specifically, the learning part 81 inputs the learning temperature distribution data Ht and the learning exposure pattern Pt as input variables and inputs the learning exposure result Rt as teaching data to the machine learning model (step S104). The learning part 81 thereafter performs machine learning according to a supervised machine learning program to make parameter adjustment for the machine learning model (step S105).

Next, the learning part 81 judges whether to make parameter adjustment again (step S106). The judgment in step S106 is made under a condition whether the parameter adjustment step S105 has been repeated a predetermined number of times for the same learning dataset, for example.

If it is judged that the parameter adjustment step S105 has not been repeated the predetermined number of times (step S106: Yes), the learning part 81 judges that parameter readjustment is necessary for the same learning dataset, and performs step S105 again.

If it is judged that the parameter adjustment step S105 has been repeated the predetermined number of times for the same learning dataset, the learning part 81 thereafter judges whether a predetermined end condition is fulfilled (step S107). The end condition may be a condition to be fulfilled if a difference between an estimated exposure result and teaching data is less than a preset threshold, for example.

If it is judged that the predetermined end condition is not fulfilled (step S107: No), the controller 10 returns to step S101, acquires a new learning dataset (steps S101 to S103), and performs machine learning using the acquired learning dataset (steps S104 to S106). In this case, steps S101 to S103 are omissible in the presence of a plurality of learning datasets acquired in advance.

If it is judged that the predetermined end condition is fulfilled (step S107: Yes), the controller 10 finishes the process of learning the machine learning model. As a result, the learned model M is generated. On the basis of temperature distribution data and an exposure pattern input to the learned model M, the learned model M is capable of estimating an exposure result with high accuracy obtained by forming an exposure pattern in line with a corresponding temperature distribution. The learning part 81 provides the generated learned model M to the estimation part 82.

### 3. Imaging Process

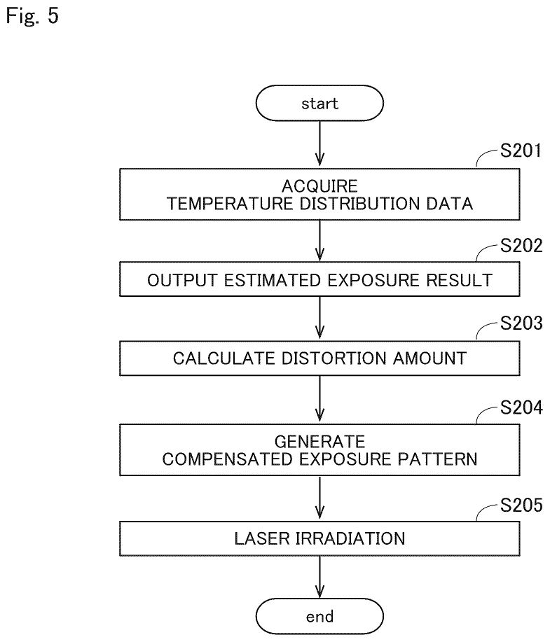

The imaging process by the imaging system 1 according to one embodiment of the present invention will be described next by referring to FIG. 5. FIG. 5 is a flowchart showing a flow of the imaging process by the imaging system 1.

In the imaging system 1, while the imaging process is performed repeatedly, changes in various conditions occur at each part of the device such as change in a temperature distribution. This may cause deviation of a laser irradiation position to reduce alignment accuracy. In response to this, the imaging system 1 performs compensation for the laser irradiation position using the learned model M that is implementable in a shorter time than calibration, making it possible to reduce a frequency of the calibration to be performed regularly. This eventually improves average takt in the imaging process on each substrate W.

Before the imaging process shown in FIG. 5, the learned model M is generated in advance by performing the above-described learning process. In the imaging process, the camera 50 first acquires the temperature distribution data Hm (step S201). Then, the camera 50 transfers the temperature distribution data Hm to the estimation part 82 of the distortion amount estimation unit 92.

Meanwhile, the exposure pattern Pi to be formed on the substrate W is input to the estimation part 82. The estimation part 82 inputs the temperature distribution data Hm and the exposure pattern Pi to the learned model M and causes the learned model M to output the estimated exposure result D1 (step S202). The estimation part 82 transfers the estimated exposure result D1 output from the learned model M to the distortion amount calculation part 83.

The distortion amount calculation part 83 compares the estimated exposure result D1 and the exposure pattern Pi to calculate the distortion amount D2 of a laser irradiation position (step S203). The distortion amount D2 is obtained through calculation, and shows a direction and a degree of distortion occurring in each area of the estimated exposure result D1 in comparison to the exposure pattern Pi. As an example, the distortion amount calculation part 83 calculates the distortion amount D2 as a vector map showing a difference in terms of a vector quantity obtained between a coordinate in the estimated exposure result D1 and a coordinate in the exposure pattern Pi about each position corresponding to a predetermined reference coordinate in the exposure pattern Pi. The distortion amount calculation part 83 transfers the calculated distortion amount D2 to the imaging control unit 93.

Next, the exposure pattern compensation part 71 of the imaging control unit 93 compensates for the exposure pattern Pi on the basis of the distortion amount D2 to generate the compensated exposure pattern Po (step S204). The exposure pattern compensation part 71 generates the compensated exposure pattern Po, for example, by deforming the exposure pattern Pi in a direction of cancelling the distortion amount D2 in each coordinate. Then, the exposure pattern compensation part 71 transfers the compensated exposure pattern Po to the imaging implementation part 72.

The imaging implementation part 72 controls the operation of the imaging processor 40 according to the compensated exposure pattern Po to irradiate the substrate W with laser, thereby forming a pattern comparable to the exposure pattern Pi on the upper surface of the substrate W (step S205).

As described above, the imaging system 1 of the present embodiment estimates a distortion amount of a laser irradiation position on the basis of the temperature distribution data Hm to compensate for the exposure pattern Pi. This makes it possible to form a pattern more approximate to the intended exposure pattern Pi on the substrate W than in a case without the compensation.

### 4. Modifications

While the embodiment of the present invention has been described above, the present invention is not to be limited to the foregoing embodiment.

### 4-1. First Modification

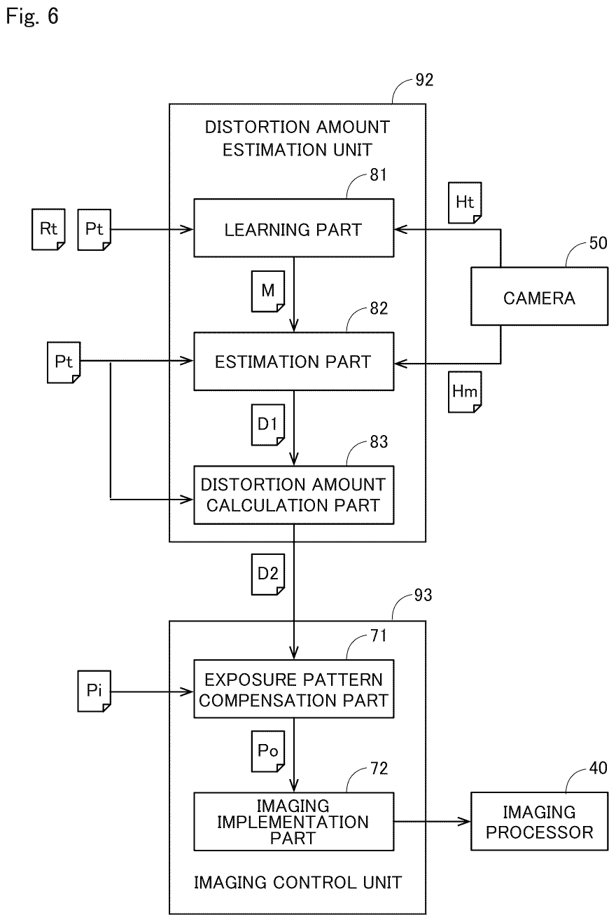

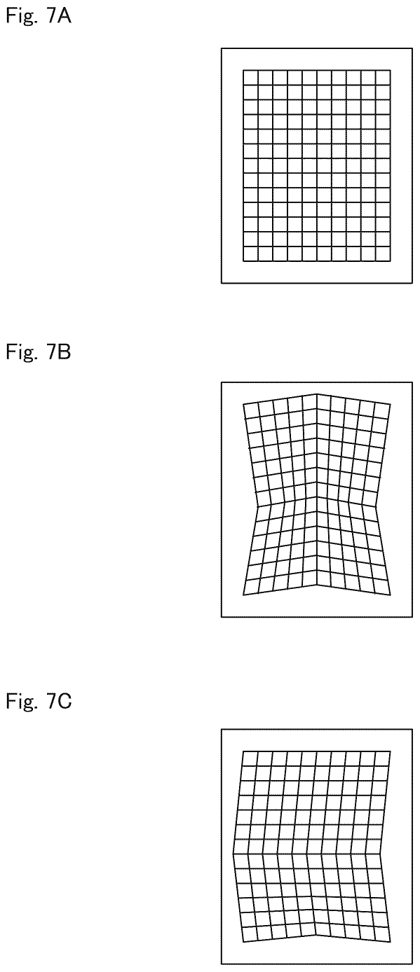

FIG. 6 is a control block diagram showing the distortion amount estimation unit 92 and the imaging control unit 93 of an imaging system according to one modification. FIG. 7 includes views showing the learning exposure pattern Pt and examples of the learning exposure result Rt according to the example in FIG. 6. According to the modification in FIG. 6, instead of the exposure pattern Pi, the learning exposure pattern Pt is further used in estimation of the distortion amount D2 of a laser irradiation position by the distortion amount estimation unit 92 in the imaging process during product manufacture in addition to being used during learning.

As shown in FIG. 7(a), the learning exposure pattern Pt used in this case is to apply laser regularly onto the substrate W. Each of FIG. 7(b) and 7(c) shows an example of the learning exposure result Rt showing an exposure result about the learning exposure pattern Pt in FIG. 7(a). As seen from these, it is possible to calculate the distortion amount D2 easily if the learning exposure pattern Pt is a regular pattern.

In the imaging process during product manufacture, the estimation part 82 inputs the temperature distribution data Hm entered from the camera 50 and the learning exposure pattern Pt to the learned model M to acquire the estimated exposure result D1. Then, the distortion amount calculation part 83 calculates the distortion amount D2 of a laser irradiation position on the basis of the learning exposure pattern Pt and the estimated exposure result D1. The distortion amount calculation part 83 transfers the calculated distortion amount D2 to the imaging control unit 93.

Like in the example in FIG. 6, the exposure pattern Pi to be subjected to exposure from now is not always required to be used for estimating the distortion amount D2.

In the above-described embodiment and modification, temperature distribution data and an exposure pattern are input variables to be input to the learned model M and an estimated exposure result is an output from the learned model M. However, the present invention is not limited to this. Only the temperature distribution data may be an input variable to be input to the learned model M, and an estimated distortion amount may be an output from the learned model M. In this case, in the process of learning the learned model M, the temperature distribution data may be used an input variable to be input to the learned model M, and a learning distortion amount may be used as teaching data that is calculated in advance from the learning exposure pattern Pt and the learning exposure result Rt.

### 4-2. Second Modification

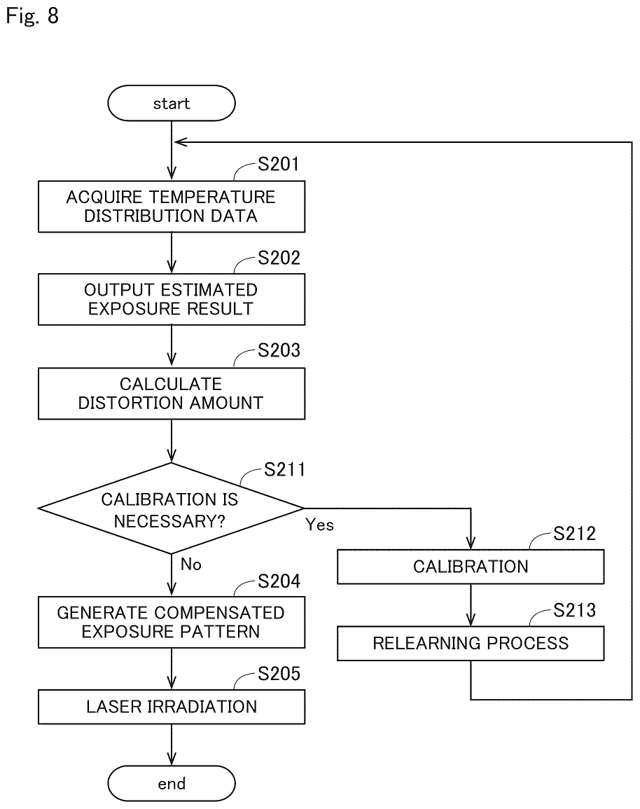

FIG. 8 is a flowchart showing a flow of an imaging process according to a different modification. According to the example in FIG. 8, timing of calibration is determined on the basis of the distortion amount D2 having been estimated by the distortion amount estimation unit 92 on the basis of the temperature distribution data Hm.

In the imaging process according to the example in FIG. 8, the controller 10 first acquires temperature distribution data (step S201), outputs the estimated exposure result D1 (step S202), and calculates the distortion amount D2 (step S203) like in the imaging process of the embodiment described above.

The controller 10 thereafter judges whether calibration is necessary on the basis of the distortion amount D2 (step S211). Regarding a condition for the judgment in step S211, if a total of the distortion amounts D2 over the entire substrate W is greater than a predetermined total threshold or if the distortion amounts D2 in all areas on the substrate W include a distortion amount D2 greater than a predetermined partial threshold, for example, calibration is judged to be necessary.

If calibration is judged not to be necessary (step S211: No), the imaging process is continued to generate a compensated exposure pattern (step S204), irradiate the substrate W with laser (step S205), and then finishes the imaging process.

On the other hand, if calibration is judged to be necessary (step S211: Yes), the controller 10 interrupts the imaging process and performs calibration (step S212). By performing calibration, a laser irradiation position is changed from that before the calibration. Thus, the learning process is performed again after the calibration (step S213). The flow thereafter returns to step S201 to restart the usual imaging process.

Like in the example in FIG. 8, the estimated distortion amount may be used for determining timing of calibration. According to the example in FIG. 8, the imaging process is interrupted and calibration is performed if the distortion amount D2 fulfills the judgment condition. However, the present invention is not limited to this. If the distortion amount D2 fulfills the judgment condition, calibration may be performed after the ongoing imaging process is finished.

### 4-3. Third Modification

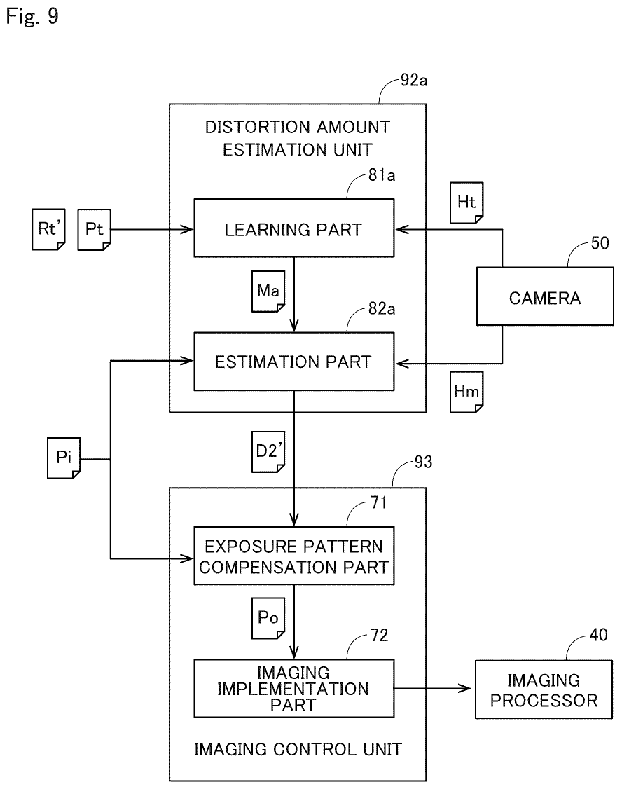

FIG. 9 is a control block diagram showing a distortion amount estimation unit 92a and the imaging control unit 93 of an imaging system according to a different modification. According to the modification in FIG. 9, in response to input of the temperature distribution data Hm and the exposure pattern Pi to a learned model Ma, the learned model Ma directly outputs an estimated distortion amount D2′ in an exposure result about the exposure pattern Pi in line with a corresponding temperature distribution. Thus, according to the example in FIG. 9, the distortion amount estimation unit 92a does not include a distortion amount calculation part. The distortion amount estimation unit 92a includes a learning part 81a and an estimation part 82a. An imaging control unit 93 according to the example in FIG. 9 is comparable to the imaging control unit 93 according to the above-described embodiment.

The learning part 81a learns a machine learning model to be used in estimation of a distortion amount by the estimation part 82a, thereby generating the learned model Ma. For implementation of a step of learning the machine learning model by the learning part 81a, the learning temperature distribution data Ht acquired by the camera 50 and the learning exposure pattern Pt are prepared in advance. Furthermore, a distortion amount is measured at each position in an exposure pattern formed on the substrate W as a result of formation of the learning exposure pattern Pt by the imaging system 1 immediately after acquisition of the learning temperature distribution data Ht, and the measured distortion amount is defined as a learning exposure result Rt′. As an example, the learning exposure result Rt′ may be calculated from a photographed image obtained by causing photographic equipment outside the imaging system 1 to photograph the substrate W on which the learning exposure pattern is formed. In another case, the learning exposure result Rt′ may be acquired by causing a user to directly make measurement at each position in an exposure pattern on the substrate W on which the learning exposure pattern is formed, for example.

The learning part 81a generates the learned model Ma through machine learning using the learning temperature distribution data Ht and the learning exposure pattern Pt as input variables and using the learning exposure result Rt′ as teaching data that is a result of measurement of a distortion amount corresponding to the learning temperature distribution data Ht. In response to input of the temperature distribution data Hm entered from the camera 50 and the exposure pattern Pi to the learned model M, the learned model M becomes capable of estimating a distortion amount in an exposure result about the exposure pattern Pi in line with a corresponding temperature distribution to output the estimated distortion amount D2′.

The estimation part 82a contains the learned model Ma generated by the learning part 81a. The estimation part 82a inputs the temperature distribution data Hm entered from the camera 50 to the learned model M, and transfers the estimated distortion amount D2′ output from the learned model M to the exposure pattern compensation part 71 of the imaging control unit 93.

As described above, an output from the learned model Ma contained in the estimation part 82a may be a distortion amount estimated directly. This realizes omission of a structure corresponding to the distortion amount calculation part 83 of the above-described embodiment.

### <4-4. Other Modifications

In the above-described embodiment, temperature distribution data is a thermal distribution image photographed using a thermography camera. However, the present invention is not limited to this. The temperature distribution data may be measured values obtained by a plurality of temperature sensors provided in a plurality of positions at an imaging system.

The elements appearing in the above embodiment and modifications may be combined together, as appropriate, without inconsistencies.

### REFERENCE SIGNS LIST

1 Imaging system
10 Controller
40 Imaging processor
50 Camera
71 Exposure pattern compensation part
72 Imaging implementation part
81, 81a Learning part
82, 82a Estimation part
83 Distortion amount calculation part
92, 92a Distortion amount estimation unit
93 Imaging control unit
D1 Estimated exposure result
D2, D2′ Distortion amount
Hm Temperature distribution data
Ht Learning temperature distribution data
M, Ma Learned model
Pi Exposure pattern
Po Compensated exposure pattern
Pt Learning exposure pattern
Rt, Rt′ Learning exposure result
W Substrate

1. An estimation method of estimating a distortion amount of a laser irradiation position in an imaging system to irradiate a base material with laser, comprising:
a) acquiring temperature distribution data representing a temperature distribution at said imaging system;
b) inputting said temperature distribution data to a learned model and acquiring an estimated exposure result that is an estimation of an exposure result output from said learned model; and
c) calculating a distortion amount of a laser irradiation position from said estimated exposure result.

2. The estimation method according to claim 1, further comprising:
d) generating said learned model through machine learning configured to said exposure result using said temperature distribution data as an input variable and using exposure result data as teaching data that corresponds to said temperature distribution data,
said step d) is performed before said steps a), b), and c).

3. The estimation method according to claim 1, wherein
a thermal distribution image is photographed as said temperature distribution data using a thermography camera in said step a).

4. The estimation method according to claim 1, wherein
using a plurality of temperature sensors provided in a plurality of positions at said imaging system, measured values are acquired from said plurality of temperature sensors as said temperature distribution data in said step a).

5. A control method for an imaging system to irradiate a base material with laser, comprising:
P) estimating a distortion amount of a laser irradiation position through the estimation method according to claim 1;
Q) acquiring an exposure pattern;
R) generating a compensated exposure pattern by compensating for a laser irradiation position in said exposure pattern on the basis of the estimated distortion amount; and
S) irradiating said base material with laser on the basis of said compensated exposure pattern.

6. A control device for an imaging system to irradiate a base material with laser, comprising:
an estimation part that inputs temperature distribution data representing a temperature distribution at said imaging system to a learned model and acquires an estimated exposure result that is an estimation of an exposure result output from said learned model;
a distortion amount calculation part that calculates a distortion amount of a laser irradiation position from said estimated exposure result;
an exposure pattern compensation part that generates a compensated exposure pattern by compensating for a laser irradiation position in an exposure pattern on the basis of the calculated distortion amount; and
an imaging implementation part that irradiates said base material with laser on the basis of said compensated exposure pattern.

7. An estimation method of estimating a distortion amount of a laser irradiation position in an imaging system to irradiate a base material with laser, comprising:
x) acquiring temperature distribution data representing a temperature distribution at said imaging system; and
y) inputting said temperature distribution data to a learned model and acquiring a distortion amount of a laser irradiation position output from said learned model.

8. A control device for an imaging system to irradiate a base material with laser, comprising:
an estimation part that inputs temperature distribution data representing a temperature distribution at said imaging system to a learned model and acquires a distortion amount of a laser irradiation position output from said learned model;
an exposure pattern compensation part that generates a compensated exposure pattern by compensating for a laser irradiation position in an exposure pattern on the basis of said distortion amount; and
an imaging implementation part that irradiates said base material with laser on the basis of said compensated exposure pattern.
